(19) United States
(12) Patent Application Publication
(10) Pub. No.: US 2026/0344423 A1
(43) Pub. Date: Oct. 29, 2026

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Pin-Jing SU, Taichung City (TW); Wen-Yu TENG, Taichung City (TW); Liang-Yi HUNG, Taichung City (TW); Cheng-Yu KANG, Taichung City (TW)

(73) Assignee: SILICONWARE PRECISION INDUSTRIES CO., LTD., Taichung City (TW)

(21) Appl. No.: 19/661,585

(22) Filed: Apr. 28, 2026

(30) Foreign Application Priority Data
Apr. 28, 2025 (TW) 114115955

(51) Int. Cl. H10W 40/20

(52) U.S. Cl. CPC H10W 40/242

(57) ABSTRACT

An electronic package and a manufacturing method thereof are disclosed. An electronic component is disposed on a carrier and a thermal interface material structure is provided on the electronic component, wherein a planar size of the thermal interface material structure is larger than a planar size of the electronic component. A heat dissipation member is then coupled to the electronic component via the thermal interface material structure, thereby preventing the thermal interface material structure from bleeding and improving heat dissipation efficiency.

### BACKGROUND

### 1. Technical Field

The present disclosure relates to a semiconductor device, and more particularly, to an electronic package and a manufacturing method thereof.

### 2. Description of Related Art

With increasing demands for electronic products for functionality and processing speed, a semiconductor chip as a core component of an electronic product requires higher density electronic circuits and components, and thus the semiconductor chip generates a large amount of heat during operation. Furthermore, since a traditional molding compound covering the semiconductor chip is a poor heat transfer material with a thermal conductivity of only 0.8 W/mK (i.e., poor heat dissipation efficiency), failure to effectively dissipate the heat generated by the semiconductor chip results in damage to the semiconductor chip and product reliability issues.

In order to rapidly dissipate heat to the outside, a heat sink is usually disposed in a semiconductor package. The heat sink is typically bonded to a back surface of the semiconductor chip via a thermal conductive material, such as a thermal interface material (TIM), so as to dissipate the heat generated by the semiconductor chip through thermal conductive material and the heat sink.

In order to conduct the heat generated by the semiconductor chip to the heat sink more quickly and effectively, liquid metal has been used as the thermal interface material in recent years to improve the conduction efficiency on a path from the semiconductor chip to the heat sink by its thermal conductivity of up to 80-128 W/mK.

However, the aforementioned semiconductor package often experiences voids generated in the liquid metal due to compression and heat between the heat sink and the semiconductor chip. It may even cause the liquid metal to bleed outside the chip placement area, resulting in a short circuit risk to electronic components located in a component arrangement area.

Therefore, how to overcome the above-mentioned problems of the prior art has become an urgent issue to be solved.

### SUMMARY

In view of the various deficiencies of the prior art, the present disclosure further provides an electronic package, which includes: a carrier; an electronic component disposed on the carrier; a thermal interface material structure disposed on the electronic component, wherein a planar size of the thermal interface material structure is larger than a planar size of the electronic component; and a heat dissipation member coupled to the electronic component via the thermal interface material structure.

The present disclosure also provides a method of manufacturing an electronic package, and the method includes: providing a carrier, and disposing an electronic component on the carrier; disposing a thermal interface material structure on the electronic component, wherein a planar size of the thermal interface material structure is larger than a planar size of the electronic component; and coupling a heat dissipation member to the electronic component via the thermal interface material structure.

In the aforementioned electronic package and the manufacturing method thereof, the thermal interface material structure includes a central area and a periphery area adjacent to the central area, wherein the central area covers the electronic component, and the periphery area is disposed around the central area and overhangs and protrudes beyond the electronic component.

In the aforementioned electronic package and the manufacturing method thereof, a thickness of the periphery area is greater than a thickness of the central area.

In the aforementioned electronic package and the manufacturing method thereof, the periphery area is not in contact with the electronic component.

In the aforementioned electronic package and the manufacturing method thereof, the planar size of the thermal interface material structure is at least 10% larger than the planar size of the electronic component.

In the aforementioned electronic package and the manufacturing method thereof, the thermal interface material structure includes a plurality of materials. For example, the thermal interface material structure includes graphite film and liquid metal.

In the aforementioned electronic package and the manufacturing method thereof, the electronic component has an active surface and a non-active surface opposing the active surface, and the electronic component is disposed on the carrier with the active surface and is electrically connected to the carrier.

In the aforementioned electronic package and the manufacturing method thereof, the heat dissipation member includes a body and a support portion extending outward from a surface of the body, the body is coupled to the electronic component via the thermal interface material structure, and the support portion is disposed on the carrier via an adhesive layer.

According to the present disclosure, the thermal interface material structure includes a plurality of materials (graphite film and liquid metal), which can simultaneously achieve low thermal resistance and good workability. Moreover, the planar size of the thermal interface material structure is larger than the planar size of the electronic component, making it less prone to bleeding and void formation, thereby improving heat dissipation efficiency.

### BRIEF DESCRIPTION OF THE DRAWINGS

FIG. 1A to FIG. 1D are schematic cross-sectional views illustrating an electronic package and a manufacturing method thereof according to the present disclosure.

### DETAILED DESCRIPTION

The following describes the embodiments of the present disclosure with examples. Those skilled in the art can readily understand additional advantages and effects of the present disclosure from the contents disclosed in this specification.

It should be understood that the structures, proportions, dimensions, and the like in the accompanying figures are only used to coordinate with the disclosure of the specification for the understanding and reading by one skilled in the art, rather than to limit the conditions under which the present disclosure may be implemented. Thus, they do not possess substantive technical significance. Any modification of the structures, alteration in proportional relationships, or adjustment to dimensions without affecting the effects produced and the purposes achieved by the present disclosure should still be considered within the scope defined by the technical contents disclosed in the present specification. Additionally, terms such as “on,” “first,” “second,” “a,” and the like in the specification are solely for clarity of description, rather than to limit the scope in which the present disclosure may be implemented. Therefore, alterations or adjustments to their relative relationships without substantially changing the technical contents should also be regarded as within the implementable scope of the present disclosure.

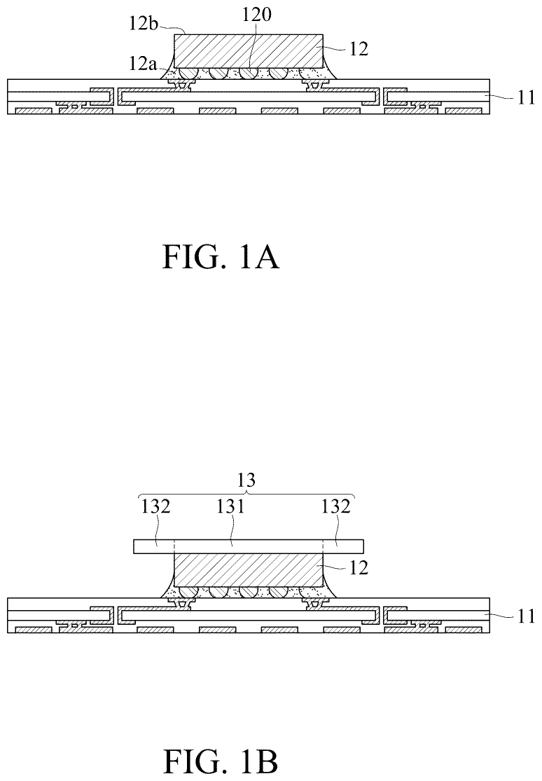

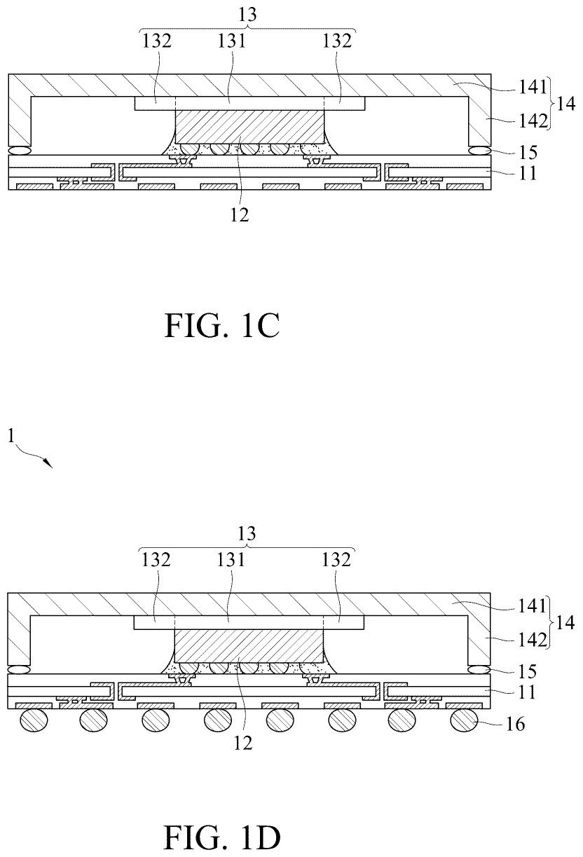

Please refer to FIG. 1A to FIG. 1D, which are schematic cross-sectional views illustrating an electronic package and a manufacturing method thereof according to the present disclosure.

As shown in FIG. 1A, a carrier 11 is provided, and an electronic component 12 is disposed on the carrier 11.

The carrier 11 is, for example, a substrate with a core layer and a circuit structure, or a coreless circuit structure, which includes a dielectric layer and a circuit layer (such as a redistribution layer). Alternatively, the carrier 11 may also be a lead frame, a silicon interposer, a wafer, or other plates with metal routing, and is not limited to the above.

The electronic component 12 is disposed on the carrier 11 and is electrically connected to the circuit layer. The electronic component 12 may be an active component, a passive component, a package structure, or a combination thereof. The active component may be a semiconductor chip. And the passive component may be, for example, a resistor, a capacitor, and an inductor. In one embodiment, the electronic component 12 is a semiconductor chip having an active surface 12a and a non-active surface 12b opposing the active surface 12a, and the active surface 12a is electrically connected to the carrier 11 through a plurality of conductive bumps 120 in a flip-chip manner.

As shown in FIG. 1B, a thermal interface material (TIM) structure 13 is disposed on the non-active surface 12b of the electronic component 12. A planar size of the thermal interface material structure 13 is larger than a planar size of the electronic component 12 (for example, at least 10% larger than the planar size of the electronic component 12). The thermal interface material structure 13 includes a central area 131 and a periphery area 132 adjacent to the central area 131. The planar size of the central area 131 is substantially the same as the planar size of the electronic component 12 to cover the electronic component 12, and the periphery area 132 is disposed around the central area 131 and overhangs and protrudes beyond the electronic component 12.

In one embodiment, the thermal interface material structure 13 includes only one material, such as an indium sheet or other metal sheets, or a plurality of materials such as graphite film combined with liquid metal, to simultaneously achieve low thermal resistance and good workability.

In one embodiment, a thickness of the periphery area 132 is greater than a thickness of the central area 131. In another embodiment, the periphery area 132 is not in contact with the electronic component 12.

As shown in FIG. 1C, a heat dissipation member 14 is provided. The heat dissipation member 14 includes a body 141 and a support portion 142 extending outward from a surface of the body 141. The body 141 of the heat dissipation member 14 is coupled to the electronic component 12 via the thermal interface material structure 13, while the support portion 142 of the heat dissipation member 14 is erected on the carrier 11 via an adhesive layer 15. The heat dissipation member 14 is made of, for example, copper.

As shown in FIG. 1D, a plurality of conductive components 16 are disposed on another side of the carrier 11 opposing the electronic component 12 to obtain the electronic package 1. Subsequently, the electronic package 1 may be electrically connected to an external device (e.g., a circuit board) through the plurality of conductive components 16.

The present disclosure further provides an electronic package 1, comprising: a carrier 11; an electronic component 12 having an active surface 12a and a non-active surface 12b opposing the active surface 12a, wherein the electronic component 12 is disposed on the carrier 11 with the active surface 12a and is electrically connected to the carrier 11; a thermal interface material structure 13 is disposed on the electronic component 12, wherein a planar size of the thermal interface material structure 13 is larger than a planar size of the electronic component 12, and the thermal interface material structure 13 includes a central area 131 and a periphery area 132 adjacent to the central area 131, the periphery area 132 is disposed around the central area 131 and overhangs and protrudes beyond the electronic component 12; and a heat dissipation member 14 is coupled to the electronic component 12 via the thermal interface material structure 13.

The thermal interface material structure 13 combines graphite film and liquid metal, and the planar size of the thermal interface material structure 13 is at least 10% larger than the planar size of the electronic component 12, so that the increased area (the periphery area 132) of the thermal interface material structure 13 generates resistance, preventing the liquid metal from being extruded. Furthermore, the pressurized liquid metal fills pores on the surface of the thermal interface material structure 13 to improve surface wettability, thereby effectively reducing thermal resistance.

The heat dissipation member 14 includes a body 141 and a support portion 142 extending outward from the surface of the body 141, so that the body 141 of the heat dissipation member 14 is coupled to the electronic component 12 via the thermal interface material structure 13, while the support portion 142 of the heat dissipation member 14 is disposed on the carrier 11 via an adhesive layer 15, so as to dissipate heat generated by the electronic component 12 during operation through the thermal interface material structure 13 and the heat dissipation member 14.

To sum up, the electronic package and the manufacturing method thereof according to the present disclosure mainly provide a thermal interface material structure including a plurality of materials (graphite film and liquid metal), which can simultaneously achieve low thermal resistance and good workability. In addition, the planar size of the thermal interface material structure is larger than the planar size of the electronic component it covers, such that when the heat dissipation member is coupled to the electronic component via the thermal interface material structure, the thermal interface material structure is less prone to bleeding and void formation, thereby improving heat dissipation efficiency.

The foregoing embodiments are provided to illustrate the principles and effects of the present disclosure rather than to limit the scope of the present disclosure. Those skilled in the art may modify and alter the above embodiments without departing from the spirit and scope of the present disclosure. Therefore, the scope of protection regarding the present disclosure should be as defined in the accompanying claims.

What is claimed is:

1. An electronic package, comprising:
a carrier;
an electronic component disposed on the carrier;
a thermal interface material structure disposed on the electronic component, wherein a planar size of the thermal interface material structure is larger than a planar size of the electronic component; and
a heat dissipation member coupled to the electronic component via the thermal interface material structure.

2. The electronic package of claim 1, wherein the thermal interface material structure includes a central area and a periphery area adjacent to the central area, the central area covers the electronic component, the periphery area is disposed around the central area and overhangs and protrudes beyond the electronic component.

3. The electronic package of claim 2, wherein a thickness of the periphery area is greater than a thickness of the central area.

4. The electronic package of claim 2, wherein the periphery area is not in contact with the electronic component.

5. The electronic package of claim 1, wherein the planar size of the thermal interface material structure is at least 10% larger than the planar size of the electronic component.

6. The electronic package of claim 1, wherein the thermal interface material structure includes a plurality of materials.

7. The electronic package of claim 1, wherein the thermal interface material structure includes graphite film and liquid metal.

8. The electronic package of claim 1, wherein the electronic component has an active surface and a non-active surface opposing the active surface, and the electronic component is disposed on the carrier with the active surface and is electrically connected to the carrier.

9. The electronic package of claim 1, wherein the heat dissipation member includes a body and a support portion extending outward from a surface of the body, the body is coupled to the electronic component via the thermal interface material structure, and the support portion is disposed on the carrier via an adhesive layer.

10. A method of manufacturing an electronic package, the method comprising:
disposing an electronic component on a carrier;
disposing a thermal interface material structure on the electronic component, wherein a planar size of the thermal interface material structure is larger than a planar size of the electronic component; and
coupling a heat dissipation member to the electronic component via the thermal interface material structure.

11. The method of claim 10, wherein the thermal interface material structure includes a central area and a periphery area adjacent to the central area, the central area covers the electronic component, the periphery area is disposed around the central area and overhangs and protrudes beyond the electronic component.

12. The method of claim 11, wherein a thickness of the periphery area is greater than a thickness of the central area.

13. The method of claim 11, wherein the periphery area is not in contact with the electronic component.

14. The method of claim 10, wherein the planar size of the thermal interface material structure is at least 10% larger than the planar size of the electronic component.

15. The method of claim 10, wherein the thermal interface material structure includes a plurality of materials.

16. The method of claim 10, wherein the thermal interface material structure includes graphite film and liquid metal.

17. The method of claim 10, wherein the electronic component has an active surface and a non-active surface opposing the active surface, and the electronic component is disposed on the carrier with the active surface and is electrically connected to the carrier.

18. The method of claim 10, wherein the heat dissipation member includes a body and a support portion extending outward from a surface of the body, the body is coupled to the electronic component via the thermal interface material structure, and the support portion is disposed on the carrier via an adhesive layer.
